(19) United States
(12) Patent Application Publication
(10) Pub. No.: US 2025/0244086 A1
(43) Pub. Date: Jul. 31, 2025

(54) HEAT EXCHANGERS

(71) Applicant: Peridot Print LLC, Palo Alto, CA (US)

(72) Inventors: Wei HUANG, Palo Alto, CA (US); Ben Mint PON, Palo Alto, CA (US); Thomas Craig ANTHONY, Palo Alto, CA (US); Harish IRRINKI, Corvallis, OR (US)

(73) Assignee: Peridot Print LLC, Palo Alto, CA (US)

(21) Appl. No.: 18/857,407

(22) PCT Filed: Apr. 19, 2022
(86) PCT No.: PCT/US2022/025334

§ 371 Date: Oct. 16, 2024

(51) Int. Cl. F28F 3/04; B33Y 30/00; F28F 13/00

(52) U.S. Cl. CPC F28F 3/04; B33Y 30/00; F28F 13/003

(57) ABSTRACT

Examples of heat exchanger are described herein. In some examples, a heat exchanger may include a flow channel. In some examples, the heat exchanger may include a lattice structure disposed in the flow channel. In some examples, the heat exchanger may include a pipe structure embedded in the lattice structure. In some examples, an end of the pipe structure is disposed in a target region of the flow channel.

### BACKGROUND

Some operations produce heat. For example, computing device processors generate heat as transistors switch to execute instructions. Light emitting diodes (LEDs) produce heat while converting an electrical current into light. Batteries produce heat during charging and discharging due to internal resistance. Vehicle engines produce heat as fuel combusts. In some examples, heat and/or overheating may damage a device and/or may cause inefficient operation.

### BRIEF DESCRIPTION OF THE DRAWINGS

FIG. 1 is a diagram illustrating a cross-sectional view of an example of a structure;

FIG. 2 is a diagram illustrating a cross-sectional view of an example of a heat exchanger;

FIG. 3 is a diagram illustrating an example of a graph of temperature over dimensions of a flow channel;

FIG. 4 is a diagram illustrating an example of a graph of flow velocity over dimensions of a heat exchanger;

FIG. 5 is a block diagram of an example of an apparatus that may be used to manufacture a structure or structures described herein;

FIG. 6 is a flow diagram illustrating an example of a method for manufacturing a structure;

FIG. 7 is a diagram illustrating a cross-sectional view of an example of a heat exchanger; and

FIG. 8 is a diagram illustrating a perspective view of an example of a heat exchanger.

### DETAILED DESCRIPTION

A heat exchanger is a device to transfer heat between mediums. For instance, a heat exchanger may be utilized to transfer heat from a heat source (e.g., processor, LED, combustion engine, battery, boiler, etc.) to a substance (e.g., fluid, water, air, etc.). In some examples, a heat exchanger may be utilized to cool a processor, engine, an LED light bulb, battery, etc. In some examples, a heat exchanger may be utilized to transfer heat from a substance (e.g., fluid, water, air, etc.) to an object (e.g., engine) or medium.

In some approaches, coolant may flow through a cold plate starting from an inlet. For instance, coolant temperature may increase along a flow path. Accordingly, the lowest temperature region on the cooling surface of the cold plate may be located at the inlet or near the inlet, which may be non-optimal because more heat may be transferred to the cold plate near or in the middle of the flow path. For instance, heat may be localized in a region of a body (e.g., a region of a surface of the body). A lowest temperature region of the cooling surface may fail to align with the localized (e.g., hottest) region of the body for cooling, resulting in non-optimal cooling.

Some examples of the techniques described herein may include heat exchangers for targeted heat transfer (e.g., cooling). Some examples of heat exchangers may include an embedded structure, such as a pipe, for directing coolant to a target region. A target region is a region (e.g., volume) of a heat exchanger for targeted heat exchange (e.g., cooling). For instance, a target region may be a region of a heat exchanger for a greatest degree of heat transfer, a central region of the heat exchanger, a region of a heat exchanger abutting a body for cooling, a region of a flow channel aligned with a body for cooling or aligned with a hottest region of a body for cooling, a region of a flow channel in a perpendicular direction from a surface of a region for cooling, etc. Directing coolant may enable a flow path to start from a target region (instead of starting at an inlet, for instance). When combined with a cooling structure (e.g., lattice structure), cooling at a target region may be enhanced relative to other approaches. In some examples, the flow path can be structured such that non-target regions may be cooled concurrently. Some examples of heat exchangers may include a cooling structure, such as a lattice structure, fins, posts, or other heat transfer structure.

Some examples of the techniques described herein may provide heat exchangers that include lattice structures to transfer heat. For instance, a heat exchanger may include a flow channel with a lattice structure, where the lattice structure serves to transfer heat from a body of the heat exchanger to fluid flowing through the flow channel.

A lattice structure is an arrangement of a member or members (e.g., branches, beams, joists, columns, posts, rods, fins, etc.). For example, a lattice structure may be structured along one dimension, two dimensions, and/or three dimensions. Examples of a lattice structure may include rods, two-dimensional grids, three-dimensional grids, gyroidal structures, cubic lattices, body-centered lattices, etc. In some examples, a lattice structure includes members disposed in a crosswise manner. For instance, two members of a lattice structure may intersect at a diagonal, perpendicular, or oblique (e.g., non-perpendicular and non-parallel) angle.

Some examples of the structures described herein may include combinations of a lattice structure with a pipe structure (e.g., pipe, tube, funnel, conduit, channel, etc.). In some examples, a lattice and another structure may form a heat exchanger for enhanced cooling performance. Because the pipe may deliver cooling fluid to a target region, cooling performance may be enhanced compared to other approaches.

In some examples, a lattice structure, pipe structure, heat exchanger, or a portion(s) thereof may be manufactured by three-dimensional (3D) printing, another manufacturing technique(s), or a combination thereof. Some examples of 3D printing that may be utilized to manufacture some examples of the structures described herein may include Fused Deposition Modeling (FDM), Multi-Jet Fusion (MJF), Selective Laser Sintering (SLS), binder jet, Stereolithography (SLA), Selective Laser Melting (SLM), Electron Beam Melting (EBM), Metal Jet Fusion, metal binding printing, liquid resin-based printing, etc. For instance, a heat exchanger or a portion thereof may be manufactured with metal 3D printing and/or another 3D printing technique.

In some examples, additive manufacturing may be used to manufacture 3D objects (e.g., geometries, lattices, etc.). Some examples of additive manufacturing may be achieved with 3D printing. For example, thermal energy may be projected over material in a build area, where a phase change and solidification in the material may occur at certain voxels. A voxel is a representation of a location in a 3D space (e.g., a component of a 3D space). For instance, a voxel may represent a volume that is a subset of the 3D space. In some examples, voxels may be arranged on a 3D grid. For instance, a voxel may be cuboid or rectangular prismatic in shape. In some examples, voxels in the 3D space may be uniformly sized or non-uniformly sized. Examples of a voxel size dimension may include 25.4 millimeters (mm)/150=170 microns for 150 dots per inch (dpi), 490 microns for 50 dpi, 2 mm, 4 mm, etc. The term “voxel level” and variations thereof may refer to a resolution, scale, or density corresponding to voxel size.

Some examples of the geometries and/or structures (e.g., lattice structures, pipe structures, etc.) described herein may be produced by additive manufacturing. For instance, some examples may be manufactured with plastics, polymers, semi-crystalline materials, metals, etc. Some additive manufacturing techniques may be powder-based and driven by powder fusion. Some examples of the geometries and/or structures (e.g., lattices) described herein may be manufactured with area-based powder bed fusion-based additive manufacturing, such as MJF, Metal Jet Fusion, metal binding printing, SLM, SLS, etc. Some examples of the approaches described herein may be applied to additive manufacturing where agents carried by droplets are utilized for voxel-level thermal modulation.

In some examples of additive manufacturing, thermal energy may be utilized to fuse material (e.g., particles, powder, etc.) to form an object (e.g., structure, geometry, lattice, etc.). For example, agents (e.g., fusing agent, detailing agent, etc.) may be selectively deposited to control voxel-level energy deposition, which may trigger a phase change and/or solidification for selected voxels.

In some examples of 3D printing, a binding agent (e.g., adhesive) may be printed onto material in a build volume to bind powder (e.g., particles) and form a precursor object (e.g., “green part”). The precursor object may be heated (in an oven or heating apparatus, for example) to sinter the precursor object and form a solid part.

Throughout the drawings, similar reference numbers may designate similar or identical elements. When an element is referred to without a reference number, this may refer to the element generally, with and/or without limitation to any particular drawing or figure. In some examples, the drawings are not to scale and/or the size of some parts may be exaggerated to more clearly illustrate the example shown. Moreover, the drawings provide examples in accordance with the description. However, the description is not limited to the examples provided in the drawings.

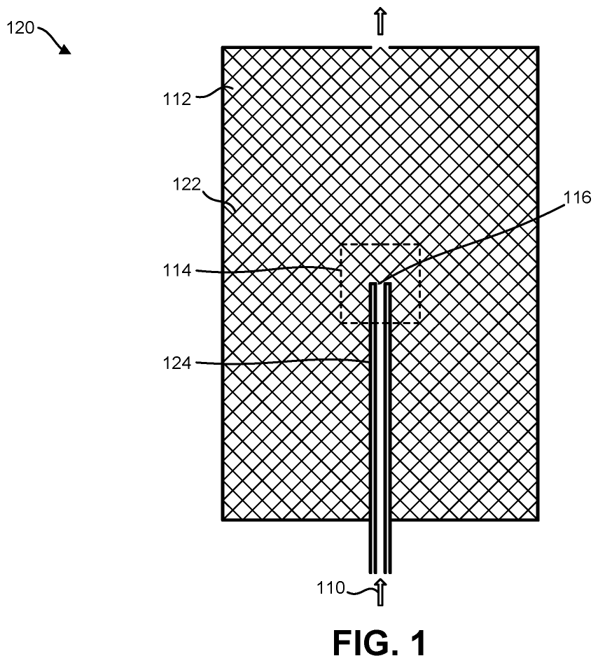

FIG. 1 is a diagram illustrating a cross-sectional view of an example of a structure 120. In some examples, the structure 120 may be a heat exchanger and/or may be included in a heat exchanger. The structure 120 may include a flow channel 112. A flow channel is a course (e.g., route, path, etc.) to carry a substance (e.g., fluid, water, air, and/or coolant, etc.). A flow channel may be bounded by a wall(s) and/or housing. For instance, the structure 120 includes the flow channel 112 bounded by a housing. In some examples, the flow channel 112 may be circular (e.g., tubular), rectangular, irregularly shaped, or a combination thereof. In some examples, the housing may provide a wall or walls that contain the flow channel 112. In some examples, the housing may have a circular (e.g., tubular) shape, rectangular shape, irregular shape, or a combination thereof. In some examples, the flow channel 112 may follow a linear, undulating, wrapping, helical, circular, and/or other path. In some examples, the flow channel 112 may be utilized to conduct the substance between an inlet and an outlet (e.g., for a portion of a course traveled between an inlet and an outlet).

The structure 120 may include a lattice structure 122. In this example, the lattice structure 122 includes members (e.g., beams) that intersect at a diagonal, perpendicular, or oblique (e.g., non-perpendicular and non-parallel) angle. In the example of FIG. 1, the members of the lattice structure 122 intersect at 90° angles. In other examples, the members of a lattice structure may intersect at a different angle or angles (e.g., 15°, 30°, 45°, 70°, 85°, 95°, 110°, 135°, etc.). In some examples, members of a lattice structure may be curved, gyroidal, interlaced, and/or intermeshed, etc.

In some examples, the lattice structure 122 may be disposed in the flow channel 112. For instance, the lattice structure 122 may partially or fully span the flow channel 112. In some examples, the lattice structure 122 may be disposed within the housing. For instance, the lattice structure 122 may be included within the housing and/or may partially or fully span between walls of the housing. In some examples, the lattice structure 122 is a 3D lattice.

In some examples, the lattice structure 122 repeats in multiple directions. For instance, a lattice structure may repeat in two dimensions or three dimensions. A repeating structure may have the same or a similar shape(s) repeating spatially. For instance, a 3D lattice structure (e.g., a cell of a lattice structure) may repeat in three dimensions (e.g., along x, y, and z axes). In some examples, a pipe structure 124 may or may not have a spatially recurring shape.

In some examples, the lattice structure 122 may permit flow. For instance, a substance (e.g., fluid, water, air, and/or coolant, etc.) may flow through the lattice structure 122 (e.g., around and/or between members of the lattice structure 122). In some examples, the structure 120 may be a single-flow heat exchanger or may be included in a single-flow heat exchanger. For instance, a heat source may be placed in contact with a heat exchanger (e.g., with a housing wall(s) of the structure 120). The heat may be conducted through the lattice structure 122. A substance flowing through the lattice structure 122 may absorb the heat from the lattice structure 122. Accordingly, the heat source may dissipate heat to the lattice structure 122, which may cool the heat source.

The structure 120 may include a pipe structure 124. A pipe structure is a hollow body. For instance, a pipe structure may be a tubular structure, cylindrical structure, funnel structure, tunnel structure, duct structure, hose structure, and/or conduit structure for conducting a substance (e.g., fluid, air, water, and/or coolant, etc.). A pipe structure may follow a linear, curved, helical, meandering, undulating, and/or other path. For instance, the pipe structure 124 may have a linear, curved, folding, twisting, helical, or coiling shape along an axial direction. While an example of a pipe structure 124 is shown in FIG. 1, other shapes may be utilized in some examples.

The pipe structure 124 may be embedded in the lattice structure 122. For instance, the pipe structure 124 may neighbor (e.g., abut, contact, etc.) a member or members of the lattice structure 122 in a direction or range of directions outward from the pipe structure 124. In some examples, the lattice structure 122 may be fused to an outer surface of the pipe structure 124. In some examples, the lattice structure 122 may be formed with the pipe structure 124. In some examples, the pipe structure 124 may transect the lattice structure 122. For instance, the pipe structure 124 may pass through a member or members of the lattice structure 122. In some examples, the pipe structure 124 may transect the lattice structure 122 by being attached along a span or spans of the lattice structure 122. In some examples, the pipe structure 124 may transect the lattice structure 122 by being geometrically merged with the lattice structure 122 (without the lattice structure 122 being disposed in a hollow portion of the pipe structure 124, for instance). For example, the pipe structure 124 may overlap with the lattice structure 122 within a volume. In some examples, the pipe structure 124 may transect the lattice structure 122 by forming a geometric (e.g., voxel) union between the pipe structure 124 and the lattice structure 122 (excluding a hollow portion of the pipe structure 124, for instance). In some examples, forming a geometric union may be accomplished using a Boolean operation. For instance, a “Boolean operation” may refer to a union operation, where multiple (e.g., two) models are united into a single model topologically. In some examples, a Boolean operation may be performed on models represented in a file(s) (e.g., a file(s) for stereolithography, an STL file(s), computer-aided design (CAD) file(s), mesh model file(s), etc.) to produce a geometric union between the models.

In some examples, the pipe structure 124 may be disposed to deliver, to a target region 114, a substance that is to pass through the lattice structure 122. An example of a flow direction 110 of the substance is illustrated in FIG. 1. In some examples, an end 116 of the pipe structure 124 is disposed in the target region 114 of the flow channel 112. For instance, an open end 116 of the pipe structure 124 may deliver the substance (e.g., fluid, coolant, etc.) to the target region 114. While the example of the target region 114 is rectangular in FIG. 1, different shapes and/or dimensionalities may be utilized for a target region in some examples. In some examples, a target region may be spherical, circular, elliptical, cuboidal, rectangular, prismatic, polygonal, amoeboid shaped, irregularly shaped, two-dimensional (2D), 3D, etc.

In some examples, the target region 114 may correspond to a heat source location (e.g., a target heat source location, anticipated heat source location, etc.). For instance, a heat source (or a region of a heat source) may be placed in contact with the structure 120 in alignment with the target region 114 illustrated in FIG. 1. For instance, a processor, a battery cell, an LED, etc., may be approximately centered over the target region 114 in contact with a wall of the structure 120. The pipe structure 124 may guide fluid to the target region 114, thereby allowing the fluid in the target region 114 to absorb heat being transferred to the lattice structure 122 from the heat source.

In some examples, multiple pipe structures and/or multiple target regions may be utilized. For instance, the structure 120 may include a second pipe structure (not shown in FIG. 1) embedded in the lattice structure 122. A second end of the second pipe structure may be disposed in a second target region of the flow channel 112. Other quantities (e.g., 3, 4, 5, etc.) of pipe structures and/or target regions may be utilized in some examples. For instance, multiple pipe structures may be routed to respective target regions. In some examples, multiple pipe structures may be routed to a single target region (e.g., the target region 114).

In some examples, the lattice structure 122 and the pipe structure 124 are 3D printed. In some approaches, the lattice structure 122 and the pipe structure 124 may be manufactured concurrently (e.g., in overlapping periods) via 3D printing. For instance, the lattice structure 122 and the pipe structure 124 may be printed concurrently (e.g., in the same build). In some examples, the lattice structure 122 may support the pipe structure 124 during manufacturing. For instance, the lattice structure 122 may perform two functions: manufacturing support and heat dissipation. In some examples, the lattice structure 122 may be a non-sacrificial support to the pipe structure 124. For instance, the lattice structure 122 may be maintained (e.g., not removed) after manufacturing. In some examples, the pipe structure 124 may be utilized to facilitate removal of unprinted material. After printing, for instance, the pipe structure 124 may allow for the passage of air (e.g., for vacuuming, for air blasting, etc.) for powder removal.

In some examples, the lattice structure 122 and the pipe structure 124 are a monolithic body. For instance, the lattice structure 122 and the pipe structure 124 may have a same or similar material composition.

In some examples, the lattice structure 122 and the pipe structure 124 may be manufactured separately. For instance, the lattice structure 122 and the pipe structure 124 may be manufactured separately (e.g., independently) and/or may be assembled. For instance, the pipe structure 124 may be manufactured with a separate technique (e.g. machining) and/or material(s) (e.g., a flexible plastic hose may be added as a liner for better thermal insulation between hot and cold fluids, etc.). In some examples, the lattice structure 122 may be manufactured and a portion removed (e.g., drilled out) to accommodate the pipe structure 124, which may be inserted into the portion.

In some examples, the structure 120 may be utilized to transfer (e.g., absorb or dissipate) heat. For instance, the structure 120 may be included within, mounted to, and/or disposed in contact with a heat source. For instance, the structure 120 (e.g., a housing wall of the structure 120) may be placed in contact with a processor, engine, LED lamp, lithium battery, computing device housing, and/or other heat source, etc., to cool the heat source. For instance, the structure 120 may be included in a processor liquid cooler. In some examples, the structure 120 may receive heated liquid and may cool the liquid (e.g., dissipate heat from the liquid).

Some examples of the techniques and/or structures described herein may provide enhanced cooling and/or performance. For instance, some examples may enhance temperature uniformity. For instance, a difference between a maximum temperature and a minimum temperature (e.g., temperature drop) of a heat exchanger may be reduced in some examples of the structures described herein. Some examples may reduce pressure drop. For instance, a pressure drop of a heat exchanger may be reduced in some examples of the structures described herein relative to other structures.

Some examples of the structures described herein may be relatively low-cost to fabricate. For instance, some examples of the techniques described herein may provide 3D manufacturing of a pipe structure embedded in a lattice structure (e.g., a heat exchanger, 3D printed cold plate, etc.), which may reduce manufacturing costs. Some examples of the structures described herein may include a variety of lattice structures and/or other heat exchange structures.

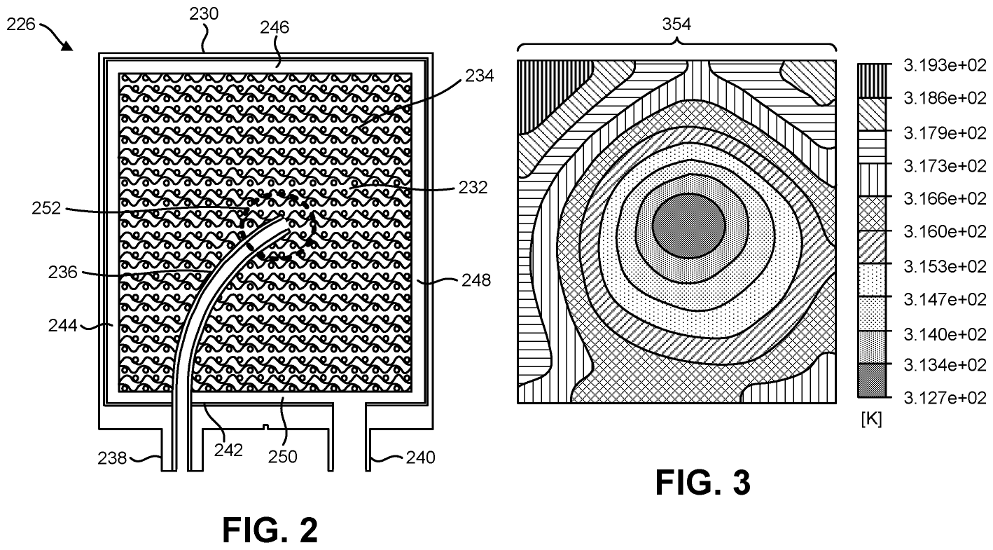

FIG. 2 is a diagram illustrating a cross-sectional view of an example of a heat exchanger 226. The heat exchanger 226 may be an example of the structure 120 described in relation to FIG. 1. In this example, the heat exchanger 226 includes a housing 230, flow channel 232, lattice structure 234, and a pipe structure 236. The heat exchanger 226 may be arranged in a cold plate design, where a heat source may be placed on top of the heat exchanger 226 and/or underneath the heat exchanger 226.

The heat exchanger 226 may include an inlet 238 disposed on the housing 230. An inlet is a passage (e.g., duct, conduit, etc.) through a housing and/or wall of a heat exchanger to permit input of a substance (e.g., fluid, coolant, water, and/or air, etc.). In some examples, an inlet may include a protruding structure (e.g., sleeve, nipple, column, threaded protrusion, etc.) on the exterior of a heat exchanger. In some examples, an inlet may include a recess (e.g., threaded recess, socket, pressure fit recess, etc.) on the exterior of a heat exchanger. In some examples, an inlet may include a sealing mechanism(s) (e.g., gasket, O-ring, etc.). In the example of FIG. 2, the inlet 238 protrudes on the housing 230 of the heat exchanger 226.

The heat exchanger 226 may include an outlet 240 disposed on the housing 230. An outlet is a passage (e.g., duct, conduit, etc.) through a housing and/or wall of a heat exchanger to permit output of a substance (e.g., fluid, coolant, water, and/or air, etc.). In some examples, an outlet may include a protruding structure (e.g., sleeve, nipple, column, threaded protrusion, etc.) on the exterior of a heat exchanger. In some examples, an outlet may include a recess (e.g., threaded recess, socket, pressure fit recess, etc.) on the exterior of a heat exchanger. In some examples, an outlet may include a sealing mechanism(s) (e.g., gasket, O-ring, etc.). In the example of FIG. 2, the outlet 240 protrudes on the housing 230 of the heat exchanger 226.

In some examples, a pipe structure may be disposed through an inlet. In the example of FIG. 2, the pipe structure 236 is disposed through the inlet 238. For instance, the heat exchanger 226 may include the pipe structure 236 (e.g., a pipe) extending through the inlet 238 into the housing 230. The pipe structure 236 extends beyond the inlet 238 (e.g., beyond an interior wall 242). The pipe structure 236 extends to a target region 252 near the center of the flow channel 232. An end of the pipe structure 236 (e.g., pipe) may be disposed in the target region 252 in the housing 230.

In this example, the heat exchanger 226 includes a lattice structure 234. The lattice structure 234 may be a 3D lattice disposed in the housing 230. The pipe structure 236 is embedded in the lattice structure 234. For instance, a pipe may be embedded in the 3D lattice. In some examples, the heat exchanger 226 may include a lattice structure 234 (e.g., cooling lattice structure) at a scale of 2.5 mm for features and spacing. In some examples, the lattice structure 234 (e.g., the heat exchanger 226) may be capable of manufacturing through metal 3D printing.

In this example, a substance (e.g., fluid, coolant, water, and/or air, etc.) may flow into the heat exchanger 226 via the inlet 238, through the pipe structure 236, through the lattice structure 234, and out of the heat exchanger 226 via the outlet 240. For instance, fluid may pass from the end of the pipe structure 236 (e.g., pipe) in the target region 252 to absorb heat from the lattice structure 234 (e.g., 3D lattice) and pass to the outlet 240. Accordingly, the substance may flow through the lattice structure 234 of the heat exchanger 226 while absorbing heat from the lattice structure 234.

In the example of FIG. 2, the inlet 238 and the outlet 240 are disposed on a same side of the heat exchanger 226. In some examples, an inlet and an outlet may be on a same side, on different sides, on opposite sides, on adjacent sides, etc., of a heat exchanger. For instance, some heat exchangers may have a height constraint (e.g., limitation) that may limit placement of the inlet and the outlet to a side or sides of a heat exchanger. For instance, a height constraint may restrict an inlet and/or outlet from being disposed on a top and/or bottom of a heat exchanger. In some examples, a heat exchanger may have a width and/or length constraint(s) that may limit placement of the inlet and/or outlet on a top, bottom, and/or other side of the heat exchanger. Some examples of the techniques described here may enable targeted heat exchange (e.g., cooling), even for cases where an inlet location and/or an outlet location are constrained. For instance, a pipe structure may deliver a substance to a target region, where an inlet and/or outlet may be disposed on any side of a heat exchanger. For example, a pipe structure may deliver coolant to a target region, even when an inlet and/or outlet are on sides or a same side of a heat exchanger.

In some examples, a structure (e.g., heat exchanger 226) may include a channel between a lattice structure and an interior wall of a flow channel. In the example of FIG. 2, the heat exchanger 226 includes a channel 250 (e.g., interior channel) between the lattice structure 234 and the interior wall 242 of the heat exchanger 226. For instance, the channel 250 may be a gap (in the flow channel 232) between an outer edge of the lattice structure 234 and an inner surface of the housing 230. The example of FIG. 2 also illustrates a second channel 244, third channel 246, and fourth channel 248. The channel 250, second channel 244, third channel 246, and fourth channel 248 may provide similar flow resistance in flow directions (e.g., four flow directions, all flow directions, etc.) from the target region 252.

In some examples, a pipe structure may cross (e.g., bridge) a channel within a flow channel. For instance, the pipe structure 236 illustrated in FIG. 2 crosses the channel 250 from the interior wall 242 to the lattice structure 234 (e.g., into the lattice structure 234).

In some examples, a lattice structure may be attached to an interior wall or walls of a housing. For instance, the lattice structure 234 may be attached to top and bottom interior walls of the housing 230. In some examples, a lattice structure may be suspended within a flow channel on a pipe structure. For instance, a lattice structure may be suspended on a pipe structure without contacting an interior wall or walls of a housing.

FIG. 3 is a diagram illustrating an example of a graph 354 of temperature over dimensions of a flow channel. For instance, the graph 354 illustrates temperature in Kelvin (K) over spatial dimensions of the flow channel 232 of FIG. 2. As illustrated in FIG. 3, a lowest temperature region corresponds to the target region 252 of the flow channel 232 (e.g., the target region 252 is within the lowest temperature region as illustrated in FIG. 3). In this example, the temperature increases as the substance flows outward from the end of the pipe structure 236 through the lattice structure 234. Some examples of the structures and/or techniques described herein may enhance heat exchanger performance (e.g., reduce temperature and/or pressure drop). For instance, the examples of FIG. 2 and FIG. 3 illustrate a lower temperature in a target region (e.g., 312.7 K (−0.9° Celsius (C))) relative to a heat exchanger without a lattice structure or pipe structure.

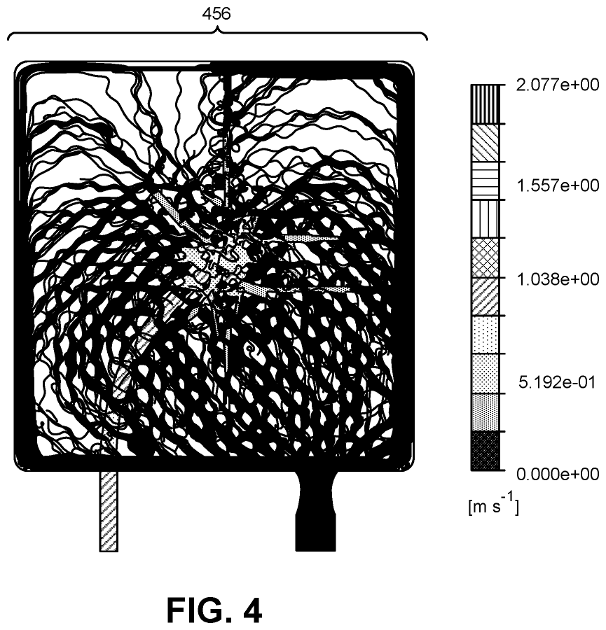

FIG. 4 is a diagram illustrating an example of a graph 456 of flow velocity over dimensions of a heat exchanger. For example, FIG. 4 illustrates flow paths of the substance. For instance, the graph 456 illustrates flow velocity in meters per second (m s⁻¹) over spatial dimensions of the heat exchanger 226 of FIG. 2. As illustrated in FIG. 4, flow velocity may be higher in the pipe structure 236 and lower through the lattice structure 234. For instance, flow velocity may be reduced as the substance flows through the lattice structure 234 (and partially around the pipe structure 236, for instance). In some examples, the approaches of FIG. 2 and FIG. 4 may result in a reduced pressure drop (e.g., 1420 pascals (Pa) (−26.3%)) relative to a heat exchanger without a lattice structure or pipe structure.

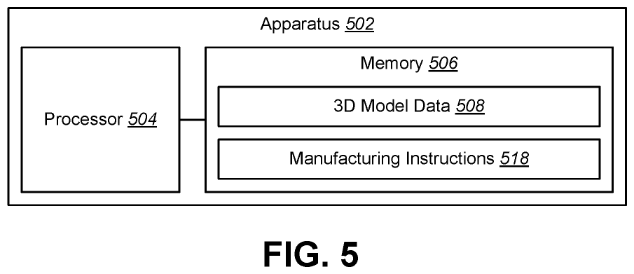

FIG. 5 is a block diagram of an example of an apparatus 502 that may be used to manufacture a structure or structures described herein. The apparatus 502 may be a computing device, such as a personal computer, a server computer, a printer, a 3D printer, a smartphone, a tablet computer, etc. The apparatus 502 may include and/or may be coupled to a processor 504 and/or to a memory 506. The processor 504 may be in electronic communication with the memory 506. In some examples, the apparatus 502 may be in communication with (e.g., coupled to, have a communication link with) a manufacturing device (e.g., a 3D printing device). In some examples, the apparatus 502 may be an example of a 3D printing device. The apparatus 502 may include additional components (not shown) and/or some of the components described herein may be removed and/or modified without departing from the scope of this disclosure.

The processor 504 may be any of a central processing unit (CPU), a semiconductor-based microprocessor, graphics processing unit (GPU), field-programmable gate array (FPGA), an application-specific integrated circuit (ASIC), and/or other hardware device suitable for retrieval and execution of instructions stored in the memory 506. The processor 504 may fetch, decode, and/or execute instructions (e.g., manufacturing instructions 518) stored in the memory 506. In some examples, the processor 504 may include an electronic circuit or circuits that include electronic components for performing a functionality or functionalities of the instructions (e.g., manufacturing instructions 518). In some examples, the processor 504 may be utilized to manufacture one, some, or all of the structures described in relation to one, some, or all of FIGS. 1-2 and/or 7-8.

The memory 506 may be any electronic, magnetic, optical, or other physical storage device that contains or stores electronic information (e.g., instructions and/or data). Thus, the memory 506 may be, for example, Random Access Memory (RAM), Electrically Erasable Programmable Read-Only Memory (EEPROM), a storage device, an optical disc, and the like. In some implementations, the memory 506 may be a non-transitory tangible machine-readable storage medium, where the term “non-transitory” does not encompass transitory propagating signals.

In some examples, the apparatus 502 may also include a data store (not shown) on which the processor 504 may store information. The data store may be volatile and/or non-volatile memory, such as Dynamic Random-Access Memory (DRAM), EEPROM, magnetoresistive random-access memory (MRAM), phase change RAM (PCRAM), memristor, flash memory, and the like. In some examples, the memory 506 may be included in the data store. In some examples, the memory 506 may be separate from the data store. In some approaches, the data store may store similar instructions and/or data as that stored by the memory 506. For example, the data store may be non-volatile memory and the memory 506 may be volatile memory.

In some examples, the apparatus 502 may include a communication interface (not shown) through which the processor 504 may communicate with an external device or devices (not shown), for instance, to receive and/or store information pertaining to an object or objects (e.g., geometry(ies), lattice(s), pipe structure(s), etc.) to be manufactured. The communication interface may include hardware and/or machine-readable instructions to enable the processor 504 to communicate with the external device or devices. The communication interface may enable a wired and/or wireless connection to the external device or devices. In some examples, the communication interface may further include a network interface card and/or may also include hardware and/or machine-readable instructions to enable the processor 504 to communicate with various input and/or output devices. Examples of input devices may include a keyboard, a mouse, a display, another apparatus, electronic device, computing device, etc., through which a user may input instructions into the apparatus 502. In some examples, the apparatus 502 may receive 3D model data 508 from an external device or devices (e.g., 3D scanner, removable storage, network device, etc.).

In some examples, the memory 506 may store 3D model data 508. The 3D model data 508 may be generated by the apparatus 502 and/or received from another device. Some examples of 3D model data 508 include a CAD file(s), a 3D manufacturing format (3MF) file(s), object shape data, mesh data, geometry data, etc. The 3D model data 508 may indicate the shape of an object or objects. For instance, the 3D model data 508 may indicate the shape of a geometry or geometries (e.g., regular and/or irregular geometries), a lattice structure or structures, and/or a pipe structure or structures for manufacture. In some examples, the 3D model data 508 may indicate a shape of one, some, or all of the geometry(ies), lattice(s), pipe structure(s), heat exchanger(s), etc., described herein.

In some examples, the processor 504 may execute the manufacturing instructions 518 to control a printhead to print a 3D lattice structure. In some examples, the processor 504 may control a printhead and/or may send instructions to a 3D printer to print the 3D lattice structure.

In some examples, the processor 504 may execute the manufacturing instructions 518 to control the printhead to print a pipe structure transecting the 3D lattice structure, where the pipe structure is to conduct fluid to a target region including a portion of the 3D lattice structure.

In some examples, the 3D lattice structure and the pipe structure are printed concurrently. For instance, the 3D lattice structure and the pipe structure may be printed concurrently as described in relation to FIG. 1.

In some examples, the processor 504 may execute the manufacturing instructions 518 to control the printhead to print a housing around the lattice structure. For instance, the housing, lattice structure, and/or pipe structure may be printed in a build. The housing may form a flow channel. For instance, the housing may include walls that contain a flow channel. In some examples, fluid (e.g., pressurized air, water, etc.) may be passed through the flow housing to remove binding agent residue and/or unfused powder.

In some examples, the 3D lattice structure may support the pipe structure during sintering. For instance, the 3D lattice structure may support the pipe structure as described in relation to FIG. 1. In some examples of metal 3D printing, for instance, the 3D lattice structure and the pipe structure may be printed as precursor objects and then sintered to join the metal particles and burn off the binding agent. During sintering, some structures may be prone to deformation, gravity slump, etc. In some examples of the techniques described herein, the 3D lattice structure may support the pipe structure during sintering to reduce deformation and/or enhance object manufacturing accuracy. In some examples of oven sintering, the 3D lattice structure may reduce (e.g., prevent) sagging in the pipe structure due to gravity. In some examples of laser sintering (e.g., SLM, EBM, etc.), the 3D lattice structure may reduce (e.g., prevent) deformation in the pipe structure due to residue stress.

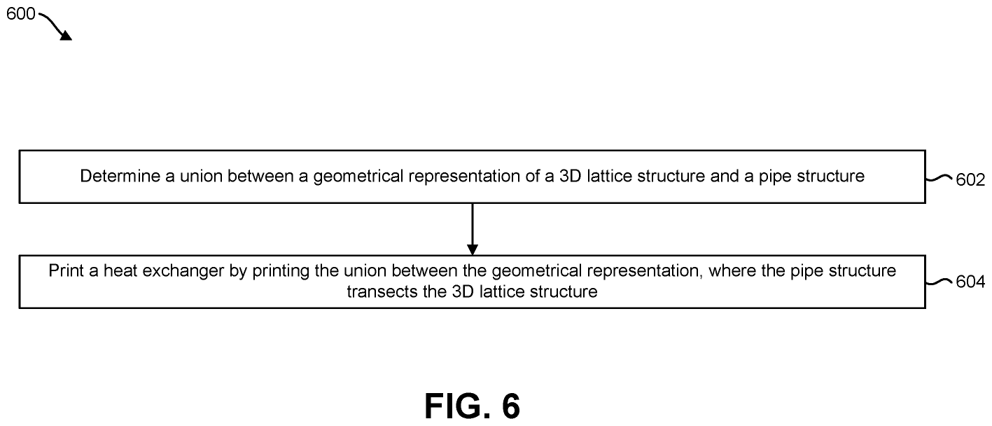

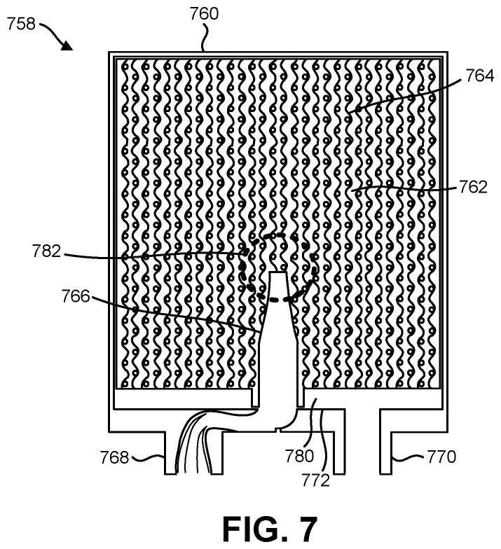

FIG. 6 is a flow diagram illustrating an example of a method 600 for manufacturing a structure. The method 600 and/or an element or elements of the method 600 may be performed by an apparatus (e.g., electronic device). For example, the method 600 may be performed by the apparatus 502 described in relation to FIG. 5.

The apparatus may determine 602 a union between a geometrical representation of a 3D lattice structure and a pipe structure. For example, the apparatus may store 3D model data representing a 3D lattice structure and 3D model data representing a pipe structure (or other pipe structure, for instance). In some examples, the apparatus may determine 602 the union by determining a combination of the 3D lattice structure and the pipe structure in 3D space. In some examples, first data representing the 3D lattice structure may be a set of voxels in 3D space, where voxels occupied by the 3D lattice structure are labeled (e.g., labeled with a ‘1’). Second data representing the pipe structure may be a set of voxels in 3D space, where voxels occupied by the pipe structure are labeled (e.g., labeled with a ‘1’). Non-occupied voxels may also be indicated (e.g., labeled with a ‘0’). In some examples, the union between the geometrical representation of the 3D lattice structure and the pipe structure may be determined by performing a voxel-wise OR operation between the first data and the second data. The resulting voxels labeled as occupied (e.g., with a ‘1’) may indicate the union between the geometrical representation of the 3D lattice structure and the pipe structure. In some examples, unoccupied voxels within the pipe structure may be maintained as unoccupied (e.g., ‘0’) or may be reverted to unoccupied (e.g., ‘0’) after the voxel-wise OR operation. For instance, an AND operation between the 3D lattice structure and voxels inside of the pipe structure may be performed to avoid setting unoccupied voxels within the pipe structure as occupied (e.g., to avoid partial obstruction and/or plugging the pipe structure).

The apparatus may print 604 a heat exchanger by printing the union between the geometrical representation of the 3D lattice structure and the pipe structure (or other pipe structure, for instance), where the pipe structure transects the 3D lattice structure. For instance, the apparatus may be a 3D printer and/or may send instructions to a 3D printer to print the 3D lattice structure and the pipe structure. In some examples, the apparatus may utilize a geometrical model (e.g., CAD file(s), 3MF file(s), etc.) that specifies the shape (e.g., mesh, voxels, etc.) of the union. For example, the apparatus may control a printhead to print the 3D lattice structure and the pipe structure according to the voxels representing the union between the geometrical representation of the 3D lattice structure and the pipe structure (without printing voxels maintained as unoccupied inside the pipe structure, for instance). In some approaches (e.g., MJF), the union may be printed with fusing agent and fused using a thermal lamp to solidify the 3D lattice structure and the pipe structure. In some approaches (e.g., Metal Jet Fusion), the union may be printed with binding agent (e.g., glue) to form a precursor object (e.g., “green part”). The precursor object may be heated in an oven to solidify the 3D lattice structure and the pipe structure. In some examples, a thickness of the pipe structure may be similar to or different from a thickness of the 3D lattice structure.

In some examples, the apparatus may print multiple pipe structures (e.g., pipe structures) that transect the 3D lattice structure in a flow channel of the heat exchanger. For instance, the apparatus may print a second pipe structure that transects the 3D lattice structure in a channel of the heat exchanger.

Some examples of the techniques described herein may provide approaches to produce many types of lattice structures and/or other heat exchange features. For instance, some of the manufacturing approaches described herein may be executed on a computing device and/or 3D printer, which may provide relatively low design and/or manufacturing costs.

FIG. 7 is a diagram illustrating a cross-sectional view of an example of a heat exchanger 758. The heat exchanger 758 may be an example of the structure 120 described in relation to FIG. 1. In this example, the heat exchanger 758 includes a housing 760, flow channel 762, lattice structure 764, and a pipe structure 766. The heat exchanger 758 may be arranged in a cold plate design, where a heat source may be placed on top of the heat exchanger 758 and/or underneath the heat exchanger 758.

The heat exchanger 758 may include an inlet 768 disposed on the housing 760. In the example of FIG. 7, the inlet 768 protrudes on the housing 760 of the heat exchanger 758.

The heat exchanger 758 may include an outlet 770 disposed on the housing 760. In the example of FIG. 7, the outlet 770 protrudes on the housing 760 of the heat exchanger 758.

In the example of FIG. 7, the pipe structure 766 is disposed through the inlet 768. For instance, the heat exchanger 758 may include the pipe structure 766 (e.g., a pipe) extending through the inlet 768 into the housing 760. The pipe structure 766 extends beyond the inlet 768 (e.g., beyond an interior wall 772). The pipe structure 766 extends to a target region 782 in the flow channel 762. An end of the pipe structure 766 (e.g., pipe) may be disposed in the target region 782 in the housing 760. The pipe structure 766 is embedded in the lattice structure 764. For instance, a pipe may be embedded in a 3D lattice. In the example of FIG. 7, the pipe structure 766 has a funnel or nozzle shape.

In this example, a substance (e.g., fluid, coolant, water, and/or air, etc.) may flow into the heat exchanger 758 via the inlet 768, through the pipe structure 766, through the lattice structure 764, and out of the heat exchanger 758 via the outlet 770. For instance, fluid may pass from the end of the pipe structure 766 (e.g., pipe) in the target region 782 to absorb heat from the lattice structure 764 (e.g., 3D lattice) and pass to the outlet 770. Accordingly, the substance may flow through the lattice structure 764 of the heat exchanger 758 while absorbing heat from the lattice structure 764.

In the example of FIG. 7, the heat exchanger 758 includes a channel 780 (e.g., interior channel) between the lattice structure 764 and an interior wall 772 of the heat exchanger 758. For instance, the pipe structure 766 illustrated in FIG. 7 crosses the channel 780 from the interior wall 772 to the lattice structure 764 (e.g., into the lattice structure 764).

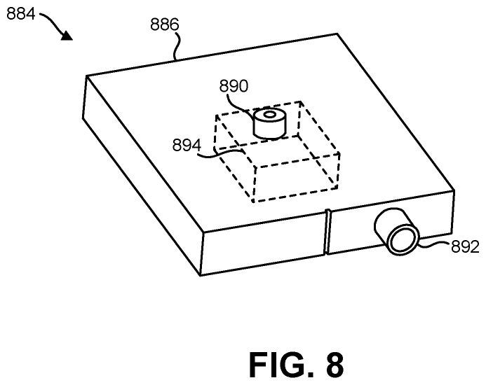

FIG. 8 is a diagram illustrating a perspective view of an example of a heat exchanger 884. The heat exchanger 884 may be an example of the structure 120 described in relation to FIG. 1. In this example, the heat exchanger 884 includes a housing 886, inlet 890, and/or outlet 892. In some examples, the heat exchanger 884 may include an internal flow channel and/or lattice structure (not shown in FIG. 8). The heat exchanger 884 may be arranged in a cold plate design, where a heat source may be placed underneath the heat exchanger 884.

In the example of FIG. 8, the inlet 890 protrudes on the housing 886 (e.g., top side of the housing 886) of the heat exchanger 884. In the example of FIG. 8, the outlet 892 protrudes on the housing 886 (e.g., front side of the housing 886) of the heat exchanger 884.

In some examples, an inlet may be disposed near a target region. For instance, an inlet may be disposed on an exterior of a housing and/or heat exchanger in alignment with a target region (e.g., overlapping with a line along a dimension from the target region). For instance, an inlet may be disposed on an opposite side of a housing wall from a target region. In the example of FIG. 8, the inlet 890 is disposed on an opposite side of a wall of the heat exchanger 884 from the target region 894. Locating an inlet near a target region may reduce the distance that a substance travels within a heat exchanger before reaching a target region. Reducing the distance traveled may allow delivery of the substance at a target temperature to a target region. For instance, cooler fluid may be delivered to a target region with an inlet nearer to a target region than with an inlet further from a target region.

In this example, a substance (e.g., fluid, coolant, water, and/or air, etc.) may flow into the heat exchanger 884 via the inlet 890, and out of the heat exchanger 884 via the outlet 892. For instance, fluid may pass from the inlet 890 to the target region 894 to absorb heat from a lattice structure (e.g., 3D lattice) and pass to the outlet 892.

In some examples, the heat exchanger 884 may not include a pipe structure. For instance, a substance may pass through the inlet into the heat exchanger 884 (e.g., to the target region 894) without a pipe structure.

In some examples, the heat exchanger 884 may include a pipe structure (not shown in FIG. 8) disposed through the inlet 890. For instance, the heat exchanger 884 may include a pipe structure (e.g., a pipe) extending through the inlet 890 into the housing 886. A pipe structure may extend beyond the inlet 890 into the target region 894. For instance, an end of a pipe structure may be disposed in the target region 894 in the housing 886. The pipe structure may be embedded in a lattice structure (e.g., 3D lattice). In some examples, the heat exchanger 884 may or may not include internal channels along internal walls.

While some of the examples described herein describe heat exchangers for absorbing heat, some examples of the techniques and structures described herein may be utilized to radiate heat and/or to warm an object or medium. For instance, heated fluid may be passed into a heat exchanger to radiate heat from the heat exchanger (to warm a cold engine, to heat air, for instance).

As used herein, the term “and/or” may mean an item or items. For example, the phrase “A, B, and/or C” may mean any of: A (without B and C), B (without A and C), C (without A and B), A and B (but not C), B and C (but not A), A and C (but not B), or all of A, B, and C.

While various examples of systems and methods are described herein, the systems and methods are not limited to the examples. Variations of the examples described herein may be implemented within the scope of the disclosure. For example, operations, functions, aspects, or elements of the examples described herein may be omitted or combined.

1. A heat exchanger, comprising:
a flow channel;
a lattice structure disposed in the flow channel; and
a pipe structure embedded in the lattice structure, wherein an end of the pipe structure is disposed in a target region of the flow channel.

2. The heat exchanger of claim 1, wherein the lattice structure is a three-dimensional (3D) lattice.

3. The heat exchanger of claim 2, wherein the lattice structure and the pipe structure are 3D printed.

4. The heat exchanger of claim 1, further comprising a second pipe structure embedded in the lattice structure, wherein a second end of the second pipe structure is disposed in a second target region of the flow channel.

5. The heat exchanger of claim 1, further comprising an inlet, wherein the pipe structure is disposed through the inlet.

6. The heat exchanger of claim 5, wherein the inlet is disposed on an opposite side of a wall of the heat exchanger from the target region.

7. The heat exchanger of claim 1, further comprising a channel between the lattice structure and an interior wall of the flow channel.

8. The heat exchanger of claim 1, wherein the target region corresponds to a heat source location.

9. The heat exchanger of claim 1, wherein the pipe structure transects the lattice structure.

10. A heat exchanger, comprising:
a housing;
an outlet disposed on the housing;
an inlet disposed on the housing;
a pipe extending through the inlet into the housing; and
a three-dimensional (3D) lattice disposed in the housing, wherein the pipe is embedded in the 3D lattice.

11. The heat exchanger of claim 10, wherein an end of the pipe is disposed in a target region in the housing.

12. The heat exchanger of claim 11, wherein fluid is to pass from the end of the pipe in the target region to absorb heat from the 3D lattice and pass to the outlet.

13. An apparatus, comprising:
a memory;
a processor in electronic communication with the memory, wherein the processor is to:
control a printhead to print a three-dimensional (3D) lattice structure; and
control the printhead to print a pipe structure transecting the 3D lattice structure, wherein the pipe structure is to conduct fluid to a target region including a portion of the 3D lattice structure.

14. The apparatus of claim 13, wherein the 3D lattice structure and the pipe structure are printed concurrently.

15. The apparatus of claim 13, wherein the processor is to control the printhead to print a housing around the lattice structure.
